(19) United States
(12) Patent Application Publication
(10) Pub. No.: US 2011/0210368 A1
(43) Pub. Date: Sep. 1, 2011

(54) MICRO-COMPOSITE PATTERN LENS, AND METHOD FOR MANUFACTURING SAME

(75) Inventors: Ki Hun Jeong, Daejeon (KR); Sun Ki Chae, Chungcheongnam-do (KR); Hyuk Jin Jung, Chungcheongnam-do (KR); Jae Jun Kim, Daegu (KR)

(73) Assignee: Korea Advanced Institute of Science and Technology, Daejeon (KR)

(21) Appl. No.: 13/120,142

(22) PCT Filed: Sep. 22, 2008
(86) PCT No.: PCT/KR2009/005375

§ 371 Date: May 5, 2011

(30) Foreign Application Priority Data
Sep. 22, 2008 (KR) 10-2008-0092814
Sep. 22, 2009 (KR) 10-2009-0089314

(51) Int. Cl. H01L 33/58; G02B 13/14; B29C 33/42; G02B 1/12; B82Y 40/00

(52) U.S. Cl. 257/98; 359/355; 264/2.5; 264/1.38; 257/E33.073; 977/949

(57) ABSTRACT

The present invention relates to a micro-composite pattern lens and to a method for manufacturing same. The micro-composite pattern lens of the present invention has a micro-composite pattern with one or more protrusions formed on one side of the lens having a predetermined curvature, and optical polymer nanoparticles arranged in the lens. The micro-composite pattern of the lens may form a wider angle of light emission, thus enabling an LED source, which is a point light source, to be converted into a surface light source having superior luminous intensity uniformity. The lens of the present invention is advantageous in that a single lens may serve as a light guide plate, a prism plate, and a diffusion plate, this eliminating the necessity of stacking optical plates, which might otherwise be required for conventional backlight units. According to the present invention, the angle of emission of the LED source which is approximately 90 degrees can be widened to 160 degrees or higher, and the local change in the micro-pattern and the mixture of ultrafine particles may improve the luminous intensity uniformity and the angle of emission of the light source. Also, wafer levels can be manufactured using a microfluidic channel array based on three dimensional molding techniques and the mixture of ultrafine particles. In addition, the use of single lens having a wider angle of light emission reduces the number of LEDs, thus reducing manufacturing costs and heat generated by LEDs. Further, the micro-composite pattern lens of the present invention has a double curvature structure to achieve improved luminous intensity uniformity and an improved angle of light emission as compared to a single curvature structure.

### TECHNICAL FIELD

The present invention relates to micro-composite pattern lens; and, more particularly, to micro-composite pattern lens and a method for manufacturing the same which causes the light emitted from the light source to have a wider angle of light emission and superior luminous intensity uniformity.

### BACKGROUND ART

At present, various technologies have been developed to control the light by deforming a surface of the lens using elaborate Micro Electro Mechanical System (MEMS) process. Among them, a research for distributing the light in a wide and uniform manner has been drawn a great attention.

Particularly, since there are known many advantages in LEDs (Light Emitting Diodes) backlight units (hereinafter, referred to BLUs) rather than BLUs used in existing LCD-TV, the LED BLUs have been commercially applied to TV.

A function of the lens is gradually increasing since diffusivity is important in cases of LCD or LED light source for illuminating BLU. However, since domestic LED enterprises import the LED lens from Europe or Japan or provide the lens in a manner of joint development with foreign enterprises, domestic lens development is an urgent problem. Since brightness depends on lens of LEDs, the technical importance thereof is very large. Further, the lens occupy the weight of 5% or less in total LED production cost, but it is expected that the cost is higher in a case of high output LED. Particularly, the function of the lens is very important in the case of LCD BLU, the development of lens having a wider angle of light emission is requested in view of a lower cost. Even though a prior lens provided over LED has possibly improved the angle of light emission, there are problems of limiting to control the luminous intensity uniformity and requiring various composite optical plates such as a light guide plate, a prism plate, a diffusion plate when converting a point light source such as LED into a surface light source. Since the production process cost for each element is higher and accurate packaging is required, there is a limitation to reduce overall production cost and so integrated optical element is requested.

### DISCLOSURE

### Technical Problem

An object of the present invention is to provide a micro-composite pattern lens and method for manufacturing the same which causes the light emitted from the light source to have a wider angle of light emission and superior luminous intensity uniformity.

### Advantageous Effects

To achieve the object of the present invention, Further, the micro-composite pattern lens according to the present invention can form a wider angle of light emission, thus enabling an LED source, which is a point light source, to be converted into a surface light source having superior luminous intensity uniformity. Further, the lens of the present invention is advantageous in that a single lens may serve as a light guide plate, a prism plate, and a diffusion plate, thus eliminating the necessity of stacking optical plates, which might otherwise be required for conventional backlight units. Further, according to the present invention, the angle of light emission of the LED source which is approximately 90 degrees can be widened to 160 degrees or higher, and the local change in the micro-pattern and the mixture of ultrafine particles may improve the luminous intensity uniformity and the angle of emission of the light source. Also, wafer levels can be manufacture using a microfluidic channel array based on three dimensional molding techniques and the mixture of ultrafine particles. In addition, the use of single lens having a wider angle of light emission reduces the number of LEDs, thus reducing manufacturing costs and heat generated by LEDs. Further, the micro-composite pattern lens of the present invention has a double curvature structure to achieve improved luminous intensity uniformity and an improved angle of light emissions as compared to a single curvature structure.

### DESCRIPTION OF DRAWINGS

FIG. 1 is a cross sectional view showing a structure of micro-composite pattern lens according to the present invention.

FIG. 2 shows various micro-composite patterns of embodiments of micro-composite pattern lens according to the present invention.

FIG. 3 shows a micro-composite pattern lens according to first embodiment of the present invention.

FIG. 4 shows a micro-composite pattern lens according to second embodiment of the present invention.

FIG. 5 shows a micro-composite pattern lens according to third embodiment of the present invention.

FIG. 6 shows light penetration into the micro-composite pattern lens according to the present invention compared to a general micro lens.

FIG. 7 is photos of taking a picture of light distribution in the micro-composite pattern lens according to the present invention compared to the general micro lens if white light source is incident.

FIG. 8 is photos of taking a picture of luminous intensity distribution in the micro-composite pattern lens according to the present invention compared to the prior micro lens are taken.

FIG. 9 shows a light source, a path which light travels in the general dome-shaped micro lens, and the distribution of the light which passes through the general dome-shaped micro lens.

FIG. 10 shows a diffusion plate, a path which light travels in the dome-shaped micro-composite pattern lens and the distribution of the light which passes through the micro-composite pattern lens of dome shape.

FIG. 11 is photo of taking a picture of the micro-composite pattern lens according to the present invention using a Scanning Electronic Microscope (SEM).

FIG. 12 is a graph showing a luminous intensity relating to a distance and a width of a protrusion, and complex conditions of the distance and the width in the micro-composite pattern lens according to the present invention.

FIG. 13 is a process drawing illustrating a method for manufacturing the micro-composite pattern lens according to the present invention.

FIG. 14 is a view showing an apparatus which enables simultaneous multi-product of the micro-composite pattern lens according to the present invention.

FIG. 15 shows the micro-composite pattern lens having double curvature structure according to one embodiment of the present invention.

FIG. 16 is a process diagram illustrating a method of manufacturing the micro-composite pattern lens having double curvature structure according to one embodiment of the present invention.

FIG. 17 is an SEM image view of the micro-composite pattern lens having double curvature structure manufactured according to one embodiment of the present invention.

FIG. 18 is a graph measuring an angle of light emission of the LED light source.

FIG. 19 is a schematic diagram in which the micro-composite pattern lens according to the present invention is applied to the LED element.

### DETAILED DESCRIPTION OF MAIN ELEMENTS

1: substrate
2: micro-composite pattern
3: thin film layer
10: protrusion
20: nano-particle
100: lens
200: chamber

### BEST MODE

The advantages, features and aspects of the invention will become apparent from the following description of the embodiments with reference to the accompanying drawings, which is set forth hereinafter.

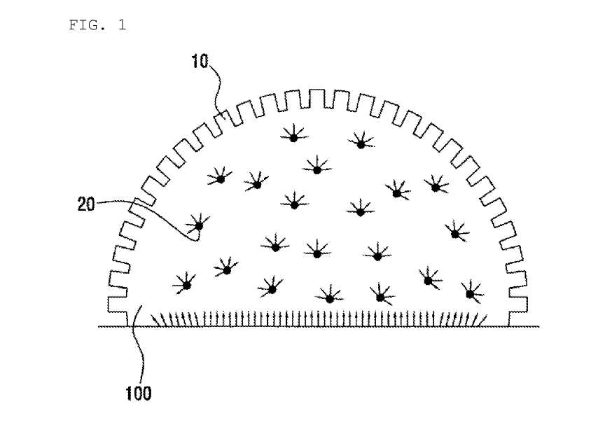

FIG. 1 is a cross sectional view showing a structure of micro-composite pattern lens according to the present invention.

Referring to FIG. 1, the micro-composite pattern lens according to the present invention has a micro-composite pattern with a plurality of protrusions 10 formed on one side of the lens 100 and contains optical polymer nano-particles arranged in the lens 100, so that the light passing through inside of the lens is scattered, reflected and diffracted by the protrusions 10 thereby to emitting the light widely and uniformly into the outside of the lens. In other words, the “micro-composite pattern lens” referred herein means a lens having micro-composite pattern with the protrusions of various shape formed thereon.

Though the micro-composite pattern lens can be made from materials such as a ultraviolet curable epoxy resin, a light curable polymer, a ceramic or the like which is a light sensitive polymer, any materials can be belonged to a range of the present invention as far as it has micro pattern formed on one side and any given curvature.

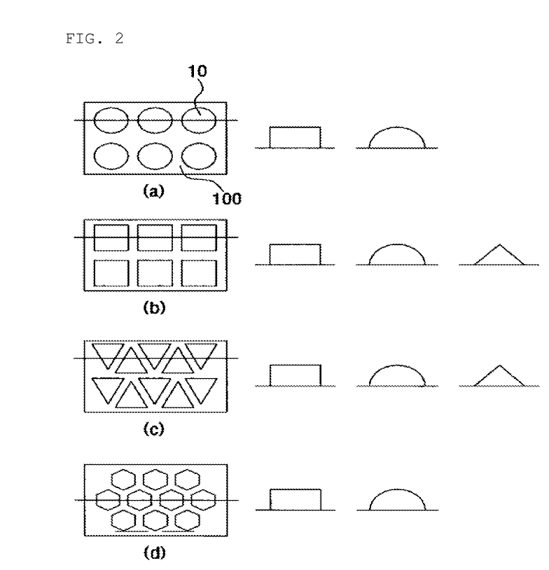

FIG. 2 shows various micro-composite patterns of embodiments of micro-composite pattern lens according to the present invention.

Referring to FIG. 2, the protrusions of micro-composite pattern can be configured with various shapes such as (a) a circle, (b) a square, (c) a triangle, (d) a hexagon, and (e) a diamond in cross-section of horizontal direction thereof.

The protrusions of the above-mentioned shape are successively arranged to form the micro-composite pattern.

Further, the vertical cross-section of the protrusions can be configured with various shapes such as a square, a semi-circle, a triangle and so on.

In this case, the three dimensional shape of the protrusions can be presented as a cylinder, a semi-spherical, a cone, a square pillar, a quadrangular pyramid, a triangular a pillar, a triangular pyramid and so on.

Herein, the height or the width of the protrusion has diversity over a wavelength of irradiating light source for the purpose of controlling the luminous intensity uniformity. The width of the protrusions is preferably formed in equal or greater than the wavelength of the light source to increase diffraction efficiency.

Herein, the protrusions formed in one side of the lens are not limited to the above-mentioned shapes, but can be configured with various shapes.

Further, the micro-composite pattern lens is not limited to shape of convex lens or concave lens, but can be manufactured in various shapes. In addition, the shape or size of the protrusions can be arranged in various forms to form the micro-composite pattern.

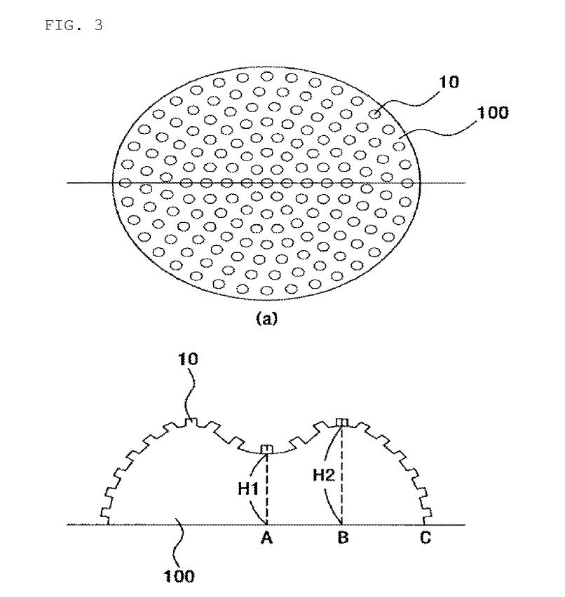

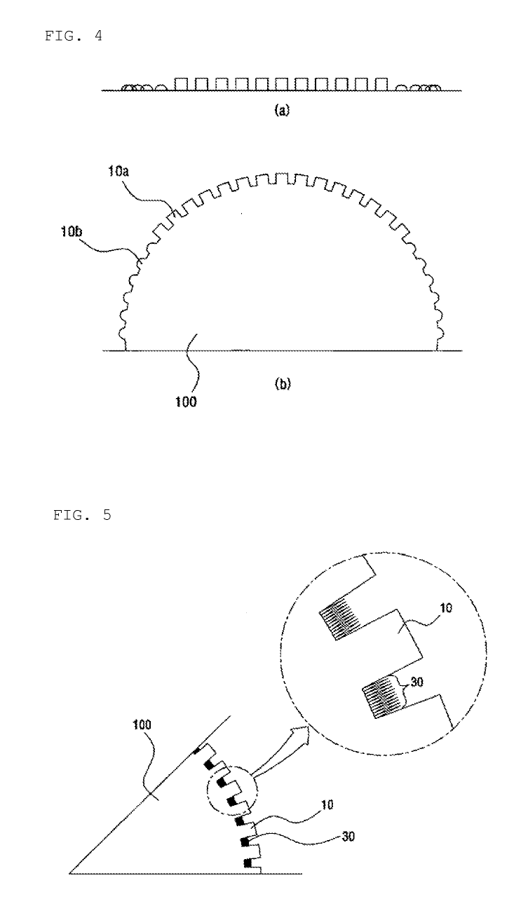

Referring to FIGS. 3 and 4, the various embodiments according to the present invention will be described.

FIG. 3 shows a micro-composite pattern lens according to first embodiment of the present invention.

In FIG. 3, (a) is a top view when being viewed from top of the lens, and (b) is a cross-sectional view taken along a vertical directional line of the lens.

A plurality of protrusions 10 is patterned on one side surface of the lens 100.

Herein, the surface curvature of the lens 100 with the protrusions formed on one side thereof is not limited to the convex lens or the concave lens, but can be manufactured in various shapes. As one example, the surface curvature can be formed in such a way to be convex in an edge portion and concaved as directing toward a center portion of the lens.

More specifically, a thickness H1 of the center portion A of the lens is formed less than a thickness H2 of a point of half the distance from the center portion A of the lens to the edge portion C of the lens.

FIG. 4 shows a micro-composite pattern lens according to second embodiment of the present invention.

In FIG. 4, (a) is a projection view projecting the micro-composite lens formed on one side of the lens surface based on a horizontal line; and (b) is a cross-sectional view taken along a vertical line of the micro-composite pattern lens.

Referring to FIG. 4, the micro-composite lens according second embodiment of the present invention has cylinder shape protrusions 10a formed on a surface proximate to the center portion of the lens and semi-cylinder shape protrusions 10b formed as directing toward the edge portion of the lens.

In other words, the protrusions of two or more shapes are formed to make composite patterns.

Further, the shape of the protrusion is configured such that the protrusions of two shapes are different from one another.

The height of the protrusions 10a is formed higher than that of the protrusions 10b.

The foregoing is only for the purpose of explaining one example, and the present invention has protrusions of various shapes arranged to form the micro-composite pattern.

FIG. 5 shows a micro-composite pattern lens according to third embodiment of the present invention.

Referring to FIG. 5, the micro-composite pattern lens according to the third embodiment of the present invention has a non-reflective layer 30 of micro-composite pattern having a ratio of height to width which is greater than a ratio of height to width of the protrusions 10 between the protrusions of the micro-composite pattern formed on one side of the lens 100.

Herein, the width of each of the micro-composite patterns is preferably formed less than wavelength (λ) of the light source emitted and the height of the micro-composite pattern is

$$\frac{λ}{4} ( 4 n + 1 ) .$$

### Herein, n is 0, 1, 2 . . . .

In this case, the non-reflective layer 30 can be formed on the protrusions of the micro-composite pattern.

As still another embodiment of the non-reflective layer, micro-thin film layer covering the protrusion and lens instead of the micro-composite pattern can be used. In this case, the non-reflective layer can be composed with one or more micro-thin film layer.

Herein, the non-reflective layer has a thickness which is ¼ of the wavelength of light source as an example and a refractive index less than that of the lens, and is made from materials including one or more from MgF2, Al2O3, ZrO2, and Parylene. The optimum refractive index of the non-reflective layer is a square root of the refractive index of the lens.

The non-reflective layer 30 minimizes the back-reflection in a direction of a LED light source due to multiple reflections.

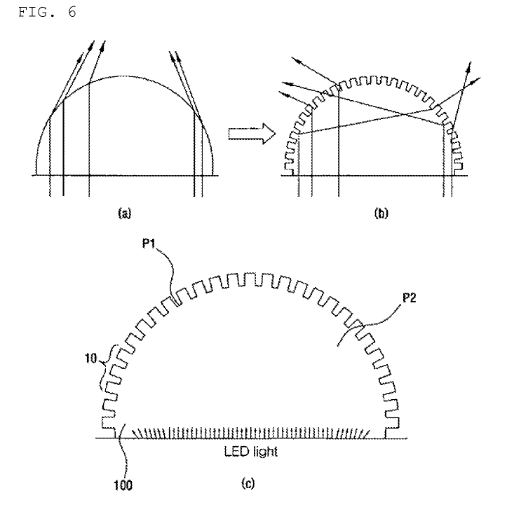

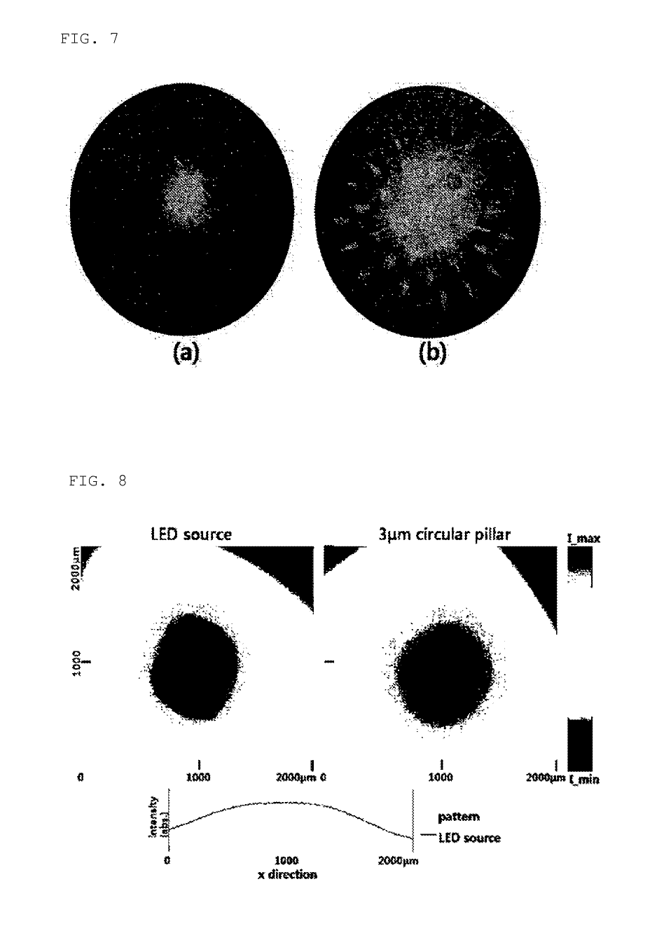

FIG. 6 shows light penetration into the micro-composite pattern lens according to the present invention compared to the general micro lens.

In FIG. 6, (a) shows that the light passing through the lens concentrates into the center portion of the lens in a case of the general micro lens, whereas (b) shows the reflection and diffraction are established at various degrees due the protrusions to form a wider angle of light emission than the general micro lens in a case of the micro-composite pattern lens according to the present invention.

Referring to (c) of FIG. 6, the micro-composite pattern lens according to the present invention can have a maximum angle of light emission by controlling factors such as a main curvature P1 of the lens, refractive index P2 of the lens material, and shape, size, period and aspect ratio of the protrusion 10.

FIG. 7 is photos of taking a picture of light distribution in the micro-composite pattern lens according to the present invention compared to the general micro lens if white light source is incident.

In FIG. 7, (a) shows light distribution image of the general micro lens having convex curvature; and (b) shows light distribution image of the micro-composite pattern lens with micro composite pattern formed on the convex surface.

It can be appreciated that the light distribution is wider and more uniform in the micro-composite pattern lens according to the present invention than the general micro lens. In this case, even though the maximum intensity of the light is reduced due to refraction pattern induced by the micro-composite pattern, the uniformity of light passing through the lens may be improved.

FIG. 8 is photos of taking a picture of luminous intensity distribution in the micro-composite pattern lens according to the present invention compared to the prior micro lens are taken.

It can be appreciated that the light intensity distribution of LED light source is more uniform in the micro-composite pattern lens according to the present invention compared to the general micro lens.

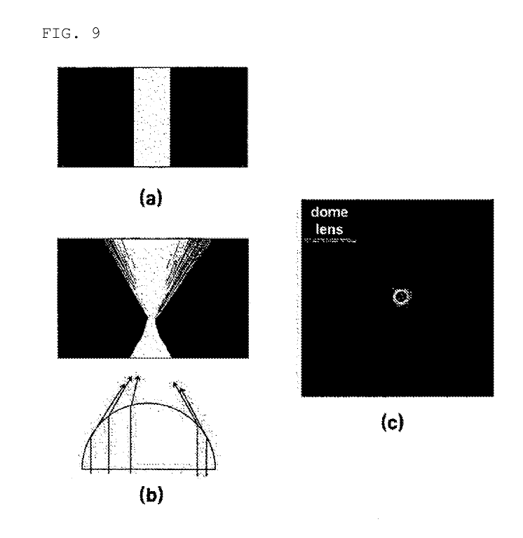

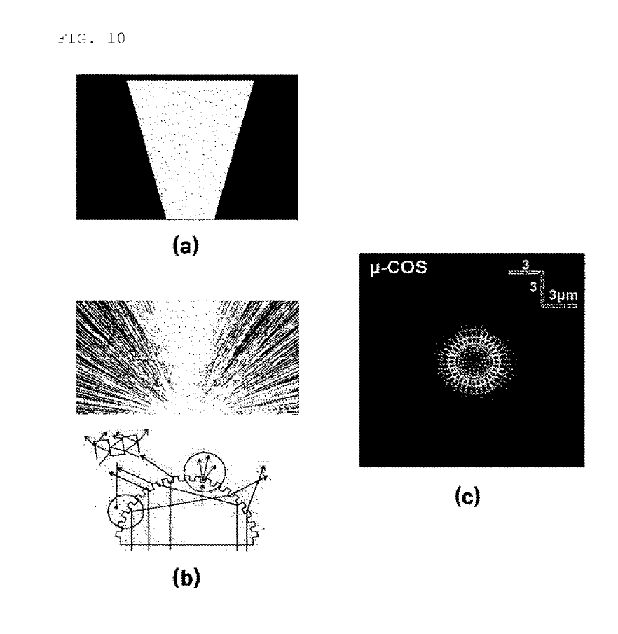

FIG. 9 and FIG. 10 are views shown by comparing a path which the white light source travels and the distribution of the light after passing through it between the micro-composite pattern lens according to the present invention and the general dome-shaped micro lens.

FIG. 9 shows that the general white light source travels straight and the light is not spread out widely but concentrated as can be known from photo of (c) taking a picture of the light distribution in front of the lens, whereas FIG. 10 shows that the light passing the lens is concentrated and spread out again as can be known from photo of taking a picture of the light passing through the general micro lens.

In FIG. 10, it can be appreciated that the light is widely spread out immediately after passing through the lens from (a) view illustrating that the light passing through the diffraction grating is spread out and (b) photo taking a picture of the light passing through the micro-composite pattern lens from the side. Further, it can be appreciated that the light is distributed evenly and widely according to the micro-composite pattern formed on one side of the lens from (c) of FIG. 10.

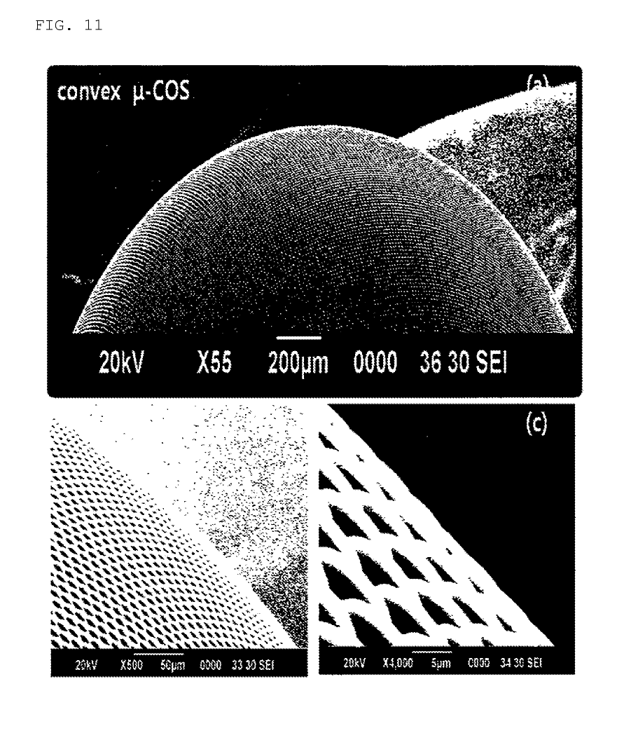

FIG. 11 is photo of taking a picture of the micro-composite pattern lens according to the present invention using a Scanning Electronic Microscope (SEM).

It can be appreciated that from (a) of FIG. 11 of taking a picture of the micro-composite pattern lens according to the present invention via the Scanning Electronic Microscope (SEM) micro protrusions are patterned, and from (b) of FIG. 11 of magnifying this picture the protrusions are shaped like micro pillar and a distance between the protrusions is about 63 μm.

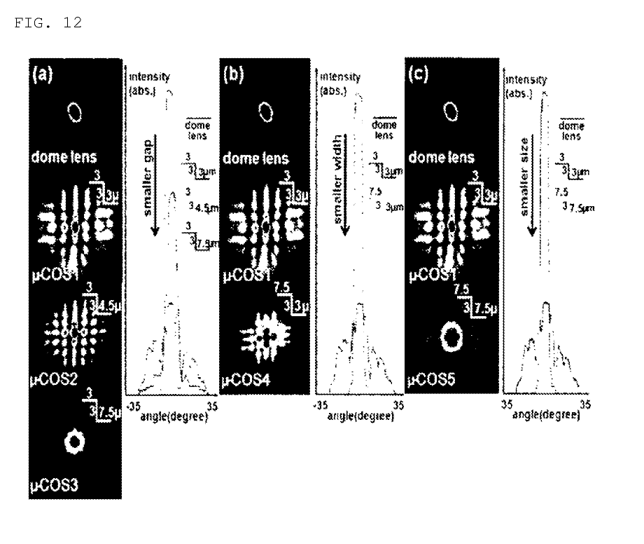

FIG. 12 is a graph showing a luminous intensity relating to a distance and a width of a protrusion, and complex conditions of the distance and the width in the micro-composite pattern lens according to the present invention. In FIG. 12, the micro-composite pattern lens according to the present invention is represented as μCOS-1 to 5 and the dimension of each protrusion is represented as white color.

From a case (a) of FIG. 12 in which the distance between the protrusions is gradually increasing while maintaining the size of the protrusion equal, it can be known that the less the distance between the protrusions, the more the angle of the light emission and the less the luminous intensity.

From a case (b) of FIG. 12 in which the width of the protrusion is gradually increasing while maintaining the distance between the protrusions equal, it can be known that the less the width of the protrusion, the more the angle of the light emission and the less the luminous intensity.

From a case (c) of FIG. 12 comparing both the distance between the protrusions and the width of the protrusion, it can be known that the less the distance between the protrusions and the width of the protrusion, the more the angle of the light emission and the less the luminous intensity.

The micro-composite pattern lens with the protrusions formed on one side in all three cases above-mentioned according to the present invention has luminous intensity uniformity, together with wider angle of light emission as compared to the general dome-shaped micro-lens.

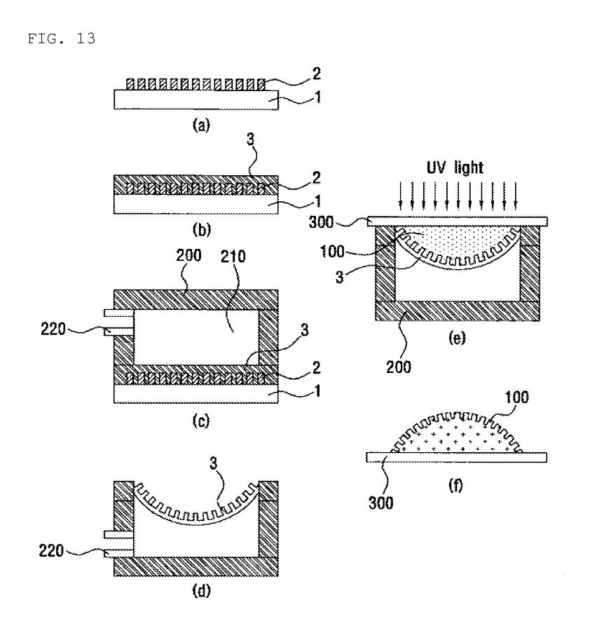

FIG. 13 is a process drawing illustrating a method for manufacturing the micro-composite pattern lens according to the present invention.

It will be explained hereinafter on the method of manufacturing the micro-composite pattern lens according to the present invention. First, the micro-composite pattern 2 is patterned on a substrate 1 to produce a template as shown in (a) of the FIG. 13. Herein, a glass substrate may be used as the substrate 1.

Next, a thin film layer 3 with elasticity is formed on the template to cover the micro-composite pattern 2 as shown in (b). Herein, the thin film layer 3 may be generally polymer material with elasticity such as synthetic resin, e.g., Polydimethylsioxane (PDMS).

A thickness of the thin film layer 3 is made higher than a height of the micro-composite pattern 2 thoroughly to cover the micro-composite pattern 2.

Next, the thin film layer 3 is bonded to an opening of a chamber 200 as shown in (c) of FIG. 13.

In this case, the thin film layer can be treated by oxygen plasma before bonding it to the chamber to remove the foreign materials.

The chamber 200 has a cavity 210 formed inside and a microfluidic channel 220 formed to connect to the cavity on one side thereof.

Then, the thin film layer 3 is removed from the template.

The thin film layer after removing the template has a pattern complementary to those of the micro-composite pattern.

Next, the thin film layer is depressed into the inside of the chamber by applying negative pressure via the microfluidic channel 220 as shown in (d). Herein, said applying the negative pressure means that the air pressure inside the chamber is made lower than the air pressure outside the chamber to discharge the air inside into outside.

Next, the depressed portion in the thin film layer 3, covered with the plate 300 is filled with the filler material 100 containing optical polymer nano-particle, covered with a substrate 300, and then applied with ultraviolet or heat thereby to cure the filler material, as shown in (e).

The filler material 100 may be ultraviolet curable polymer, heat-curable polymer and ceramic. If the filler material 100 is cured, it is exactly the micro-composite pattern lens according to the present invention, and subsequently, the lens is removed from the thin layer film 3 as shown in (f) of FIG. 13.

Subsequently, ultra thin film layer of non-reflective layer is formed on the lens as necessary. The non-reflective layer can be formed on the thin film layer 3 and cured before filling the filler material 100.

Since as a master used upon molding the lens during process of manufacturing the lens according to the present invention is used a silicone-based PDMS which is superior to deform, the original deformable lens master is manufactured and then duplicated using ultraviolet curable resin or thermosetting resin and re-duplicated as PDMS again, which results the fixed mater can be manufactured from the deformable master.

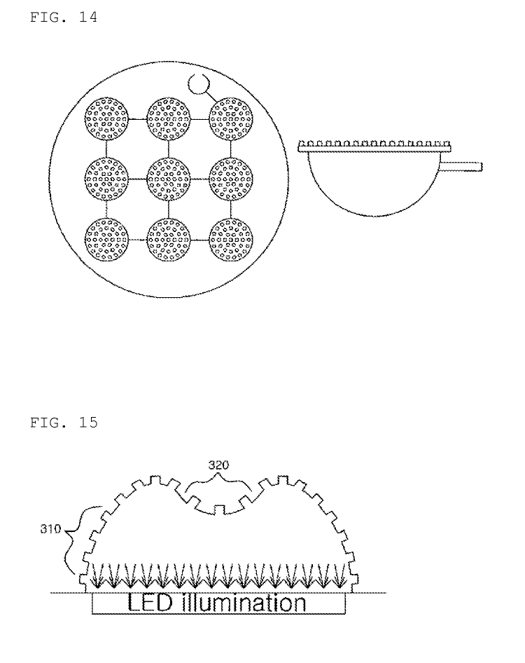

Further, the method of manufacturing the lens according to the present invention enables several deformable masters to have the same deformation under the same pressure simultaneously by connecting the deformable lens masters via microfluidic channel upon fine-molding, as shown in FIG. 14. The inventor realizes that characteristics of the lens such as the angle of light emission is improved if it is configured in double structure, i.e., structure including all curvature structure of concave lens and curvature structure of convex lens as shown in (b) of FIG. 3, as compared with the single curvature structure. Therefore, the present invention provides the method of manufacturing the micro-composite pattern lens having double curvature structure with improved optical characteristics, and the micro-composite composite patter lens having double curvature structure manufacture using the method. Hereinafter, the micro-composite pattern lens having double curvature structure will be described referring to the drawings.

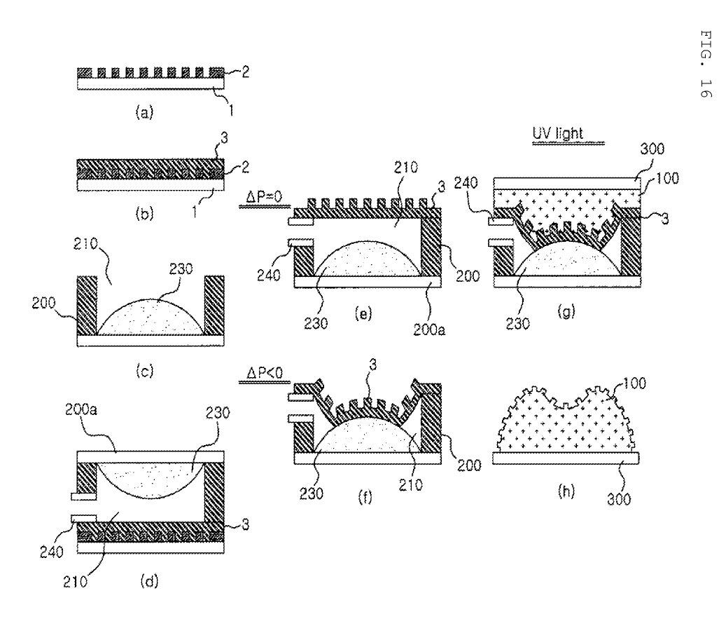

FIG. 15 is shows the micro-composite pattern lens having double curvature structure according to one embodiment of the present invention.

Referring to FIG. 15, the micro-composite pattern lens having double curvature structure according to one embodiment of the present invention has a surrounding convex portion 310 and a center concave portion 320. The micro-composite pattern lens having double curvature structure reduces hot spot of LED light source via concave curvature of the concave portion 320 and discharge the light widely. Further, the concave curvature of the center portion can control the angle of the light diffracted and increase the luminous uniformity and reflection angle of the light. Further the convex curvature of the surrounding portion couples the light with fine pattern to control the amount of light reflected from inside.

Hereinafter, the method of manufacturing the micro-composite pattern lens having double curvature structure according to the present invention will be described.

### Production Example

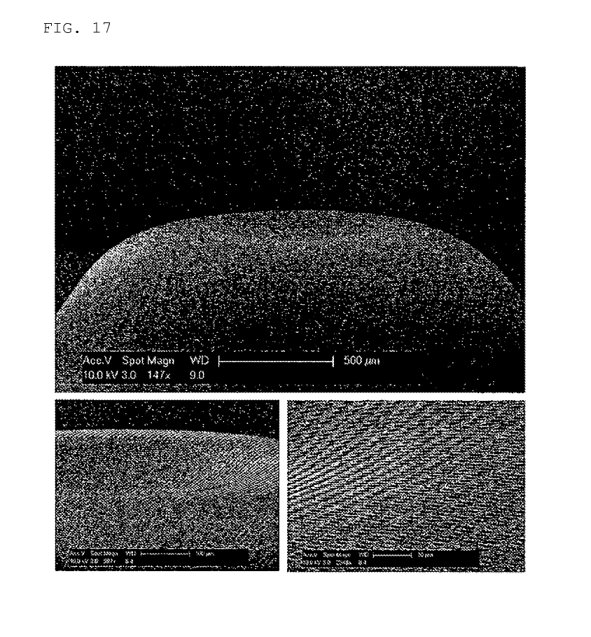

FIG. 16 is a process diagram illustrating a method of manufacturing the micro-composite pattern lens having double curvature structure according to one embodiment of the present invention.

Referring to (a) of FIG. 16, a photo-resist was stacked on a substrate and then patterned to make the micro pattern array 2. According to one embodiment of the present invention, the silicone substrate of 4 inches was washed and then water remaining over it was evaporated at a temperature of 120° C. for 30 seconds. As a result, chemical residue and organic contaminants were moved. Further, a bonding force between the photo-resist and the silicone substrate is improved due to HMDS treatment. Then, AZ1512 (AZ Electronic Materials) which is a positive photo-resist was applied to the silicone substrate and then spin-coated at 1500 rmp for 3 seconds and 450 rmp for 30 seconds, which results that the photo-resist layer of 1.2 μm is stacked on the silicone substrate. Subsequently, the positive resist is patterned at a mask aligner (MA6, SUSS MicroTec) and then developed by developer chemicals. As a result, the micro-composite array consisted of a plurality of protrusions, i.e., micro-composite pattern 2 was produced. The shape and dimension of the patterned protrusions can be variably deformed and changed depending on desired efficiency of light emission, which is within the range of the present invention.

Referring to (b) of FIG. 16, a thin film layer 3 made from material with elasticity was stacked on the micro-composite pattern 2 to cover the micro-composite pattern 2 on the substrate. Herein, the thin film layer 3 can be a polymer with elasticity such as synthetic resin, e.g., PDMS (Polydimethylsiloxane). Further, a thickness of the thin film layer 3 is made greater than a height of the micro-composite pattern 2 thoroughly to cover the micro-composite pattern 2, and therefore the shape and dimension of micro-composite pattern 2 can be implemented on the thin film layer 3.

According to one embodiment of the present invention, using PDMS thin layer (Sylgard 184, Dow Corning) as the thin film layer 3, it was applied, stacked and then spin coated on the micro-composite pattern 2. Before doing the spin coating, anti-stiction coating (Trichloro(1H,1H,2H,2H-perfluorooctly)silane, 97%, Sigma-Aldrich Products Incorporated, St. Louis, Mo.) was performed on the micro-composite pattern 2 to facilitate removing the thin film layer with elasticity.

Referring to (c) to (e) of FIG. 16, the elastic layer 200 (shown in (c) of FIG. 16) having a cavity 210 of any size formed inside was bonded and attached to the thin film layer (shown in (d) of FIG. 16), and then the substrate was removed (as shown in (e) of FIG. 16). According to one embodiment, the elastic layer 3 was PDMS, a diameter of the cavity is 2.6 mm, and microfluidic channel 240 was formed in the cavity. As a result, the air pressure within the cavity can be controlled by the micro channel 240.

According to one embodiment of the present invention, within the cavity 210 a spherical shape portion 230 such as convex lens was provided in an opposite face 200a which is opposite to the thin film layer 3. The spherical shape portion 230 preferably has a diameter smaller than that of the micro-composite pattern 3 based on a center point of the thin film layer. The material of the spherical shape portion is UV-curable epoxy resin, but is only one example and the range of the present invention is not limited to it.

Referring to (f) of FIG. 16, the thin film layer 3 was depressed into the cavity 210, more specifically toward the spherical shape portion 230 within the cavity 210 by applying negative pressure via the microfluidic channel. Herein, said applying the negative pressure means that the air pressure inside the cavity 210 is made lower than outside the cavity 210 to discharge the air inside into outside. In other words, a difference between inside and outside enables the thin film layer 3 of elastic material forming one side of the cavity 210 to be depressed into the cavity 210. In this case, the thin film layer 3 is contact to the spherical shape portion 230 having curvature structure of convex lens having given height and size within the cavity, in which partial area, i.e., only center portion of the thin film layer 3 is contact to the spherical shape portion 230. As a result, the center portion of the thin film layer 3 has a structure complementary to the curvature shape of the spherical shape portion 230. However, the thin film layer which is not contact to the spherical shape portion 230, i.e., the surrounding area has curvature structure depressed into the cavity 230. Therefore, the curvature structure of the desired center portion can be decided variously depending on the contact area of the thin film layer 3 to the curvature portion 230 and a radius of the curvature.

Subsequently, referring to (g) of FIG. 16, the thin film layer 3 of so-called double structure which is configured such that the center portion is spherical-shaped and the surrounding portion is depressed into the cavity 210 was filled with the filler material 100 containing polymer nano-particle and covered with another substrate 100, e.g., glass substrate and then applied with ultraviolet or heat to cure the filler material 300. The filler material might be ultra-curable polymer, heat-curable polymer, ceramic and so on. Though a photo-curable resin, particularly UV curable resin (Norland Optical adhesive 63, Norland Products Incorporated, Cranbury) was used as the filler material according to this embodiment of the present invention, the range of the present invention is not limited to it.

If the filler material 100 is cured, it is exactly the micro-composite pattern lens of the present invention, and subsequently the lens is removed from the thin film layer as shown in (h) of FIG. 16, which is similar to (f) of FIG. 13. The curing was UV curable according to this embodiment of the present invention.

The micro-composite pattern lens obtained via the method mentioned above has the double curvature structure, i.e., the center portion of concave curvature and the surrounding portion of convex curvature, with the micro pattern formed on one side of the lens.

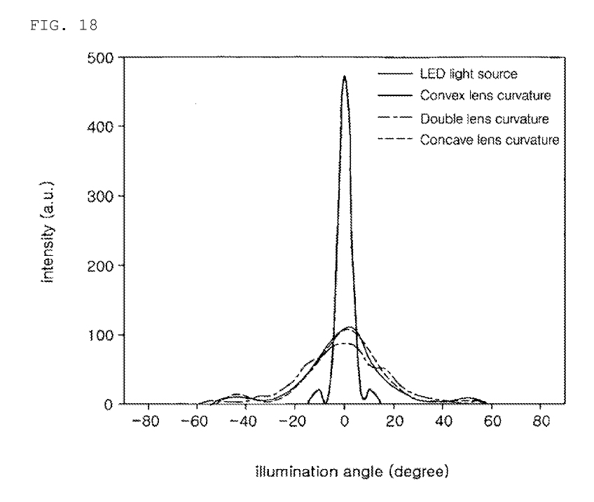

FIG. 17 is an SEM image view of the micro-composite pattern lens having double curvature structure manufactured according to one embodiment of the present invention.

Referring to FIG. 17, it will be appreciated that the center portion of the micro-composite pattern lens and the surrounding portion surrounding it have different structure, so-called double curvature structure and the micro pattern is formed on one side of the lens.

### Experimental Example

A relationship between the curvature structure of the lens and the angle of light emission was analyzed via this experimental example. The angle of the emission light of the micro-composite pattern lens having double curvature structure was measured and analyzed using optical power meter. The LED light source was used as a reference example, and micro-composite pattern lens of concave lens and convex lens having a single curvature structure was used as comparison example.

FIG. 18 is a graph measuring an angle of light emission of the LED light source.

Referring to FIG. 18, it will be appreciated that the micro-composite pattern lens having double curvature structure according to the present invention has a wider angle of light emission than the micro-composite pattern lens having single curvature structure.

The experiment result represents that the angle of light emission depends on the curvature structure of the lens and particularly the double structure is advantageous.

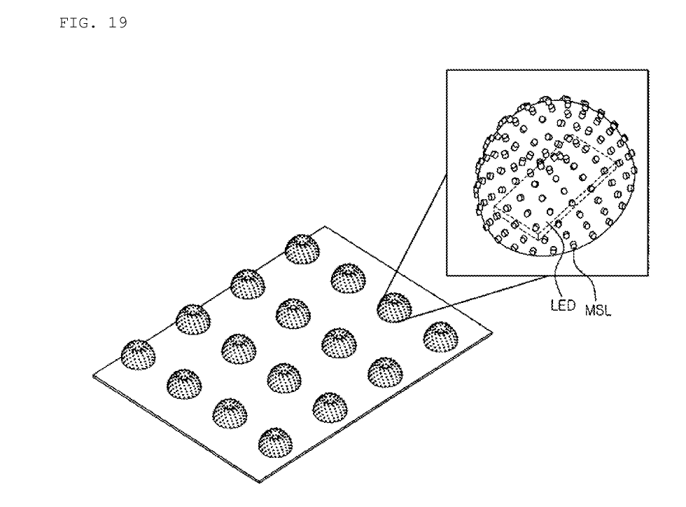

FIG. 19 is a schematic diagram in which the micro-composite pattern lens according to the present invention is applied to the LED element.

Referring to FIG. 19, the micro-composite pattern lens (MSL) having double curvature structure according to the present invention is provided on a plurality of LED light source (point light source) which is spaced from each other at a predetermined distance. Particularly, since the micro-composite pattern lens having double curvature structure according to the present invention achieve improved angle of light emission, the micro-composite pattern lens having double curvature structure provided on each of LED light sources can effectively diffuse and discharge the light emitted from each LED light source.

While the micro-composite pattern lens and the method of manufacturing the micro-composite pattern lens according to the present invention has been described referring to drawings, it will be apparent to those skilled in the art that various changes and modifications may be made without departing from the spirit and scope of the invention as defined in the following claims.

1. A micro-composite pattern lens, having a micro-composite pattern with one or more protrusions formed on one side of the lens having a predetermined curvature, and optical polymer nano-particles arranged in the lens.

2. The micro-composite pattern lens of claim 1, wherein the micro-composite pattern lens is made from at least one selected from an ultraviolet curable polymer, a heat curable polymer and a ceramic.

3. The micro-composite pattern lens of claim 1, wherein a horizontal cross-section of any one of the protrusions is shaped as one of a circle, a square, a triangle, a hexagonal, and a diamond.

4. The micro-composite pattern lens of claim 1, wherein a vertical cross-section of any one of the protrusions is shaped as one of a square, a semi-circle, and a triangle.

5. The micro-composite pattern lens of claim 1, wherein the protrusions are shaped as one of a cylinder, a semi-spherical, a cone, a square pillar, a quadrangular pyramid, a triangular pillar, a triangular pyramid, a hexagonal pillar, and a hexagonal pyramid.

6. The micro-composite pattern lens of claim 1, wherein a width of the protrusion is greater than wavelength of the light source irradiated.

7. The micro-composite pattern lens of claim 1, wherein the protrusions are formed in semi-spherical shape in an edge portion of the lens to improve an angle of light emission and luminous intensity uniformity.

8. The micro-composite pattern lens of claim 1, wherein a thickness of the micro-composite pattern lens in a half point from a center portion to the edge portion of the micro-composite pattern lens is greater than that of the center portion.

9. The micro-composite pattern lens of claim 1, wherein the micro-composite pattern lens further comprises a non-reflective layer of ultrafine pattern which is formed with a size smaller than that of the protrusion between the protrusions or over the protrusions.

10. The micro-composite pattern lens of claim 1, wherein the micro-composite pattern lens further comprises a non-reflective layer consisted of one or more micro-thin film layer formed to cover the protrusions and surface of the lens.

11. A method of manufacturing a micro-composite pattern lens having a micro-composite pattern with one or more protrusions having a cross section of a circle or a polygon formed on one side of the lens having a predetermined curvature, comprising:
patterning the micro-composite pattern on a substrate to make a template;
forming a thin film layer with material having elasticity on the template to cover the micro-composite pattern;
bonding the thin film layer to an opening of a chamber and then removing the thin film layer from the template;
applying a negative pressure to the chamber to cause the thin film layer to be depressed into the chamber;
forming the lens by filling a filler material containing optical polymer nano-particle over one side depressed into the thin film layer; and
removing the lens from the thin film layer.

12. The method of manufacturing a micro-composite pattern lens of claim 11, wherein the thin film layer is formed with PDMS (Polydimethylsiloxane).

13. The method of manufacturing a micro-composite pattern lens of claim 11, wherein the substrate is a glass substrate.

14. The method of manufacturing a micro-composite pattern lens of claim 11, wherein a thickness of the thin film layer is higher than a height of the micro-composite pattern.

15. The method of manufacturing a micro-composite pattern lens of claim 11, further comprising treating the thin film layer with oxygen plasma before bonding the thin film layer to the chamber.

16. The method of manufacturing a micro-composite pattern lens of claim 11, wherein said forming the lens further comprises:
a first process of filling a filler material of one or more of a ultraviolet curable polymer, a heat curable polymer and a ceramic over one side depressed into the thin film layer; and
a second process of curing the filler material by applying ultraviolet or heat to the filler material.

17. A method of manufacturing a micro-composite pattern, comprising:
stacking a photo-resist layer on a substrate and then patterning it to form a micro-composite pattern array;
applying the thin film layer containing material with elasticity to the micro-pattern array to stack it;
bonding one side of the elastic layer having a cavity of a given dimension to the thin film layer;
applying a negative pressure to the cavity by reducing an air pressure inside the cavity to cause the thin film layer to be depressed into the cavity;
forming the lens by filling the filler material over the thin film layer; and
removing the lens from the thin film layer, wherein the cavity is provided with a spherical shape portion having a predetermined height on an opposite face to the thin film layer.

18. The method of manufacturing a micro-composite pattern lens of claim 17, wherein the spherical shape portion in the cavity has a convex lens shape which is protruded into the thin film layer.

19. The method of manufacturing a micro-composite pattern lens of claim 17, wherein a portion of the thin film layer is contact to a surface of the spherical shape portion when the thin film layer is depressed into the cavity.

20. The method of manufacturing a micro-composite pattern lens of claim 17, wherein a center portion of the thin film layer is contact to a surface of the spherical shape portion and a surrounding portion of the thin film layer is not contact to the surface of the spherical shape portion.

21. The method of manufacturing a micro-composite pattern lens of claim 17, wherein the micro-composite pattern lens is formed with one or more of a ultraviolet curable polymer, a heat curable polymer and a ceramic.

22. The method of manufacturing a micro-composite pattern lens of claim 17, wherein the micro-composite pattern lens comprises an optical polymer nano-particle.

23. A micro-composite pattern lens, having a micro-composite pattern with a plurality of protrusions formed on one side of the lens and a double curvature structure having a curvature structure of concave lens in a center portion of the micro-composite pattern lens and a curvature structure of convex lens in a surrounding portion.

24. A LED element comprising the micro-composite pattern lens having the double curvature structure of claim 23.

25. The LED element of claim 24, wherein the micro-composite pattern lens having the double curvature structure corresponds to each of multiple LED light sources and one micro-composite pattern lens is provided in each of multiple LED light sources.

26. The LED element of claim 25, wherein the light emitted from the LED light source is diffused via the micro-composite pattern lens having the double curvature structure.
